(19) United States
(12) Patent Application Publication
(10) Pub. No.: US 2012/0064717 A1
(43) Pub. Date: Mar. 15, 2012

(54) METHOD FOR FORMING CVD-RU FILM AND METHOD FOR MANUFACTURING SEMICONDUCTOR DEVICES

(75) Inventors: Takara KATO, Nirasaki-shi (JP); Yasushi Mizusawa, Nirasaki-shi (JP); Tatsuo Hatano, Nirasaki-shi (JP); Atsushi Gomi, Nirasaki-shi (JP); Chiaki Yasumuro, Nirasaki-shi (JP); Osamu Yokoyama, Nirasaki-shi (JP)

(73) Assignee: TOKYO ELECTRON LIMITED, Tokyo (JP)

(21) Appl. No.: 13/230,351

(22) Filed: Sep. 12, 2011

Related U.S. Application Data
(63) Continuation of application No. PCT/JP10/52938, filed on Feb. 25, 2010.

(30) Foreign Application Priority Data
Mar. 12, 2009 (JP) 2009-059605

(51) Int. Cl. H01L 21/768; C23C 16/16; C23C 16/56; G06F 19/00

(52) U.S. Cl. 438/675; 700/121; 427/252; 257/E21.585

(57) ABSTRACT

In a CVD-Ru film forming method, an Ru-film is formed on a substrate by means of CVD using a ruthenium carbonyl as a film-forming material before forming a Cu film. Then the substrate on which the aforementioned Ru film is formed is annealed in a hydrogen containing atmosphere.

This application is a Continuation Application of PCT International Application No. PCT/JP2010/052938 filed on Feb. 25, 2010, which designated the United States.

### FIELD OF THE INVENTION

The present invention relates to a method for forming a CVD-Ru film used as an underlayer of Cu wiring and a method for manufacturing semiconductor devices.

### BACKGROUND OF THE INVENTION

Recently, along with demands for high speed of semiconductor devices and miniaturization and high integration of wiring patterns, it is required to decrease an inter-wiring capacitance and improve conductivity and electromigration resistance of wiring. As a technique for realizing the above goal, a Cu multilayer interconnection technique attracts attention. In this technique, Cu having higher conductivity and better electromigration resistance than those of aluminum (Al) or tungsten (W) is used as a wiring material, and a low dielectric constant film (low-k film) is used as an interlayer insulating film.

As for a method for forming Cu wiring, there is proposed a method including: forming a barrier layer made of Ta, TaN, Ti or the like on a low-k film having a trench or a hole by physical vapor deposition (PVD) represented by sputtering; forming a Cu seed layer thereon by PVD; and plating CU thereon (e.g., Japanese Patent Laid-open Publication No. H11-340226).

However, due to the trend toward miniaturization of a design rule of semiconductor devices and 32 nm nodes and beyond, it is difficult for the technique described in Japanese Patent Laid-open Publication No. H11-340226 to form a Cu seed layer in a trench or a hole by PVD with a low step coverage performance. Thus, it is expected that it is difficult to perform plating in the hole.

Therefore, there is proposed a method for forming a Ru film (CVD-Ru film) on a barrier layer by chemical vapor deposition (CVD) and plating Cu thereon (Japanese Patent Laid-open Publication No. 2007-194624). The CVD-Ru film can be formed in a fine trench or a fine hole due to its good step coverage and good adhesivity to a Cu film.

As for a technique for forming a CVD-Ru, there is known one using as a film-forming material a pentadienyl compound of ruthenium or the like (International Publication No. 2007/102333 pamphlat), or one using ruthenium carbonyl (Ru₃(CO)₁₂) (Japanese Patent Laid-open Publication No. 2007-27035). Especially when a CVD-Ru film is formed by using ruthenium carbonyl, a high-purity film can be obtained, because impurities contained in the film-forming material are basically C and O.

However, when a Cu seed layer is formed after the formation of the CVD-Ru film, wetting property of Cu to a sidewall of a hole or a trench is deteriorated. When the trench or the hole is filled by Cu plating, a void may be formed in the Cu plating.

### SUMMARY OF THE INVENTION

In view of the above, the present invention provides a method for forming a CVD-Ru film while ensuring good wetting property of Cu and a method for manufacturing semiconductor devices having the CVD-Ru film.

The present invention also provides a storage medium for storing a program for performing the semiconductor device manufacturing method.

In order to achieve the above-described objects, the present inventors have examined causes of deterioration of wetting property of Cu to the CVD-Ru film and have found that when a CVD-Ru film is used by using a film-forming material containing an organic metal compound such as ruthenium carbonyl, a large amount of carbon contained in the film forming material remains as impurities in the film, and the film surface is terminated with CO. When annealing is performed later in a nonreactive gas atmosphere to crystallize Ru, carbon on the Ru film surface and in the Ru film is segregated. In other words, carbon remaining on the Ru film surface causes deterioration of wetting property of Cu. In order to find a solution to reduce the residual carbon, the present inventors have repeated examinations. As a result, they have discovered that it is effective to perform the annealing in a hydrogen containing atmosphere or sequentially perform the annealing in a nonreactive gas atmosphere and the atmospheric exposure. The present invention has been conceived from the above result.

In accordance with a first aspect of the present invention, there is provided a CVD-Ru film forming method including: forming a Ru film on a substrate by means of CVD using a ruthenium carbonyl as a film-forming material before forming a Cu film; and annealing the substrate on which the Ru film is formed in a hydrogen containing atmosphere.

In accordance with a second aspect of the present invention, there is provided a CVD-Ru film forming method including: forming a Ru film on a substrate by means of CVD using a ruthenium carbonyl as a film-forming material before forming a Cu film; annealing the substrate on which the Ru film is formed in a nonreactive gas atmosphere; and exposing to an atmospheric the Ru film after the annealing in the nonreactive gas atmosphere.

In accordance with a third aspect of the present invention, there is provided a semiconductor device manufacturing method including: forming a metal barrier film on a substrate having a trench and/or a hole; forming a Ru film on the substrate by means of CVD using ruthenium carbonyl as a film-forming material before forming a Cu film; annealing the substrate on which the Ru film is formed in a hydrogen containing atmosphere; and forming on the annealed Ru film a Cu seed film for burying Cu plating in the trench and/or the hole.

In accordance with a fourth aspect of the present invention, there is provided a semiconductor device manufacturing method including: forming a metal barrier film on a substrate having a trench and/or a hole; forming a Ru film on the substrate by means of CVD using a ruthenium carbonyl as a film-forming material before forming a Cu film; annealing the substrate on which the Ru film is formed in a nonreactive gas atmosphere; exposing to an atmospheric the Ru film after the annealing in the nonreactive gas atmosphere; and forming on the annealed Ru film a Cu seed film for burying Cu plating in the trench and/or the hole.

In accordance with a fifth aspect of the present invention, there is provided a non-transitory computer-readable storage medium storing a program for controlling a processing apparatus, wherein the program, when executed by a computer, controls the processing apparatus to perform the semiconductor device manufacturing method described in the third aspect.

In accordance with a sixth aspect of the present invention, there is provided a non-transitory computer-readable storage medium storing a program for controlling a processing apparatus, wherein the program, when executed by a computer, controls the processing apparatus to perform the semiconductor device manufacturing method described in the fourth aspect.

### BRIEF DESCRIPTION OF THE DRAWINGS

FIG. 1 is a flowchart showing a method in accordance with a first embodiment of the present invention.

FIG. 2A is a process flowchart showing the method in accordance with the first embodiment of the present invention.

FIG. 2B is a process flowchart showing the method in accordance with the first embodiment of the present invention.

FIG. 2C is a process flowchart showing the method in accordance with the first embodiment of the present invention.

FIG. 2D is a process flowchart showing the method in accordance with the first embodiment of the present invention.

FIG. 2E is a process flowchart showing the method in accordance with the first embodiment of the present invention.

FIG. 2F is a process flowchart showing the method in accordance with the first embodiment of the present invention.

FIG. 3 schematically shows a state immediately after a CVD-Ru film is formed.

FIG. 4 schematically shows a state in which annealing is performed in a nonreactive gas atmosphere after the formation of the CVD-Ru film.

FIG. 5 schematically shows a state in which a Cu seed film is formed on the CVD-Ru film after the annealing in a nonreactive gas atmosphere.

FIGS. 6A to 6C schematically show a state in which a Cu-plated film is buried in a trench on which the Cu seed film is formed as shown in FIG. 5.

FIG. 7 schematically shows a state in which annealing is performed in a hydrogen atmosphere after the formation of the CVD-Ru film in the first embodiment of the present invention.

FIG. 8 schematically shows a state in which a Cu seed layer is formed after the annealing in a hydrogen atmosphere in the first embodiment of the present invention.

FIGS. 9A to 9C schematically show a state in which a Cu-plated film is buried in a trench on which the Cu seed layer is formed as shown in FIG. 8.

FIG. 10 is a flowchart showing a method in accordance with a second embodiment of the present invention.

FIG. 11A is a process flowchart showing the method in accordance with the second embodiment of the present invention.

FIG. 11B is a process flowchart showing the method in accordance with the second embodiment of the present invention.

FIG. 11C is a process flowchart showing the method in accordance with the second embodiment of the present invention.

FIG. 11D is a process flowchart showing the method in accordance with the second embodiment of the present invention.

FIG. 11E is a process flowchart showing the method in accordance with the second embodiment of the present invention.

FIG. 11F is a process flowchart showing the method in accordance with the second embodiment of the present invention.

FIG. 11G is a process flowchart showing the method in accordance with the second embodiment of the present invention.

FIG. 12 schematically shows a state in which a CVD-Ru film is subjected to annealing in a nonreactive atmosphere and atmospheric exposure in the second embodiment of the present invention.

FIG. 13 shows a result of analyzing concentration of C in a film thickness direction by secondary ion mass spectrometry (SIMS) in the case of forming a CVD-Ru film and performing annealing under various conditions and in the case of forming a CVD-Ru film and omitting annealing.

FIG. 14 shows comparison of a Cu-plated state between a sample of a prior art in which a CVD-Ru film is subjected to annealing in a nonreactive gas atmosphere and Cu seed film formation and a sample of the first embodiment in which a CVD-Ru film is subjected to annealing in a hydrogen containing atmosphere and Cu seed film formation.

FIG. 15 is a top view showing a multi chamber type processing apparatus used for performing the first and the second embodiment of the present invention.

FIG. 16 is a cross sectional view showing a CVD-Ru film forming unit installed at the processing apparatus of FIG. 15.

FIG. 17 is a cross sectional view showing an annealing unit which is installed at the processing apparatus of FIG. 15 and performs annealing in a hydrogen containing atmosphere of the first embodiment.

FIG. 18 is a cross sectional view showing an annealing unit which is installed at the processing apparatus of FIG. 15 and performs annealing of the second embodiment.

### DETAILED DESCRIPTION OF THE EMBODIMENTS

Hereinafter, the embodiments of the present invention will be described with reference to the accompanying drawings which form a part hereof.

### First Embodiment

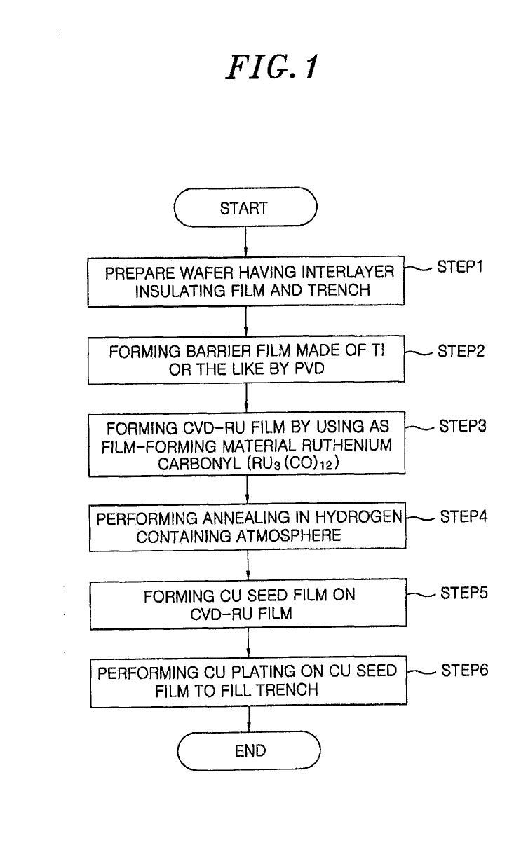

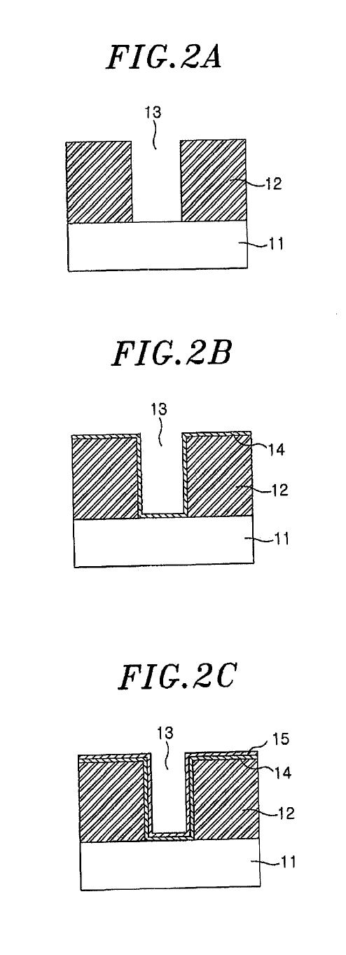

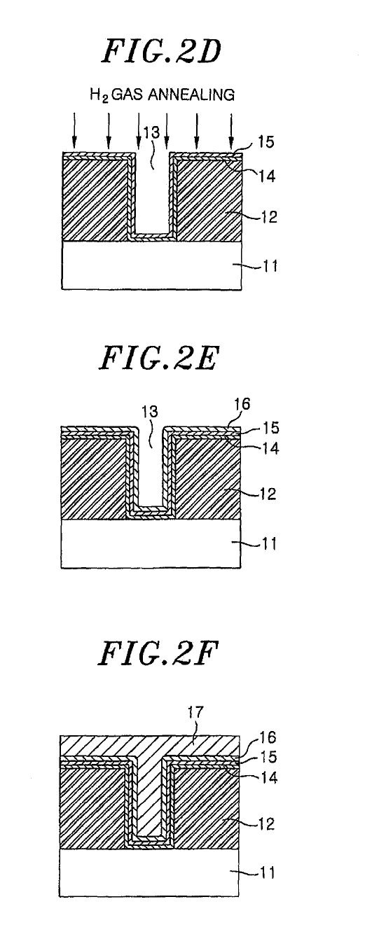

First of all, a first embodiment will be described. FIG. 1 is a flowchart showing a method in accordance with the first embodiment of the present invention. FIGS. 2A to 2F are process cross sectional views illustrating the method of the first embodiment.

In the first embodiment, first of all, there is prepared a semiconductor wafer (hereinafter, simply referred to as a wafer) in which an interlayer insulating film 12 such as an SiO₂ film or the like is formed on a Si substrate 11 and a trench 13 is formed thereon (step 1, FIG. 2A). Next, a barrier film 14 made of Ti or the like having a thickness of about 1 to 10 nm, e.g., about 4 nm, is formed on the entire surface including the trench 13 by PVD, e.g., sputtering or the like (step 2, FIG. 2B). Then, a CVD-Ru film 15 having a thickness of about 1 to 5 nm, e.g., about 4 nm, is formed on the barrier film 14 by using as a film-forming material ruthenium carbonyl (Ru₃(CO)₁₂) that is an organic metal compound (step 3, FIG. 2C). Thereafter, annealing is performed on the wafer on which the CVD-Ru film is formed in a hydrogen containing atmosphere (step 4, FIG. 2D). Next, a Cu seed film 16 having a thickness of about 5 to 50 nm, e.g., about 20 nm, is formed on the CVD-Ru film 15 by, e.g., PVD (step 5, FIG. 2E). Then, Cu plating 17 is performed on the Cu seed film 16 to fill the trench 13 (step 6, FIG. 2F).

In the CVD-Ru film forming process of step 3, the CVD-Ru film 15 is formed on the barrier film 14 by supplying ruthenium carbonyl (Ru₃(CO)₁₂) onto the barrier film 14 while heating the wafer in a depressurized atmosphere.

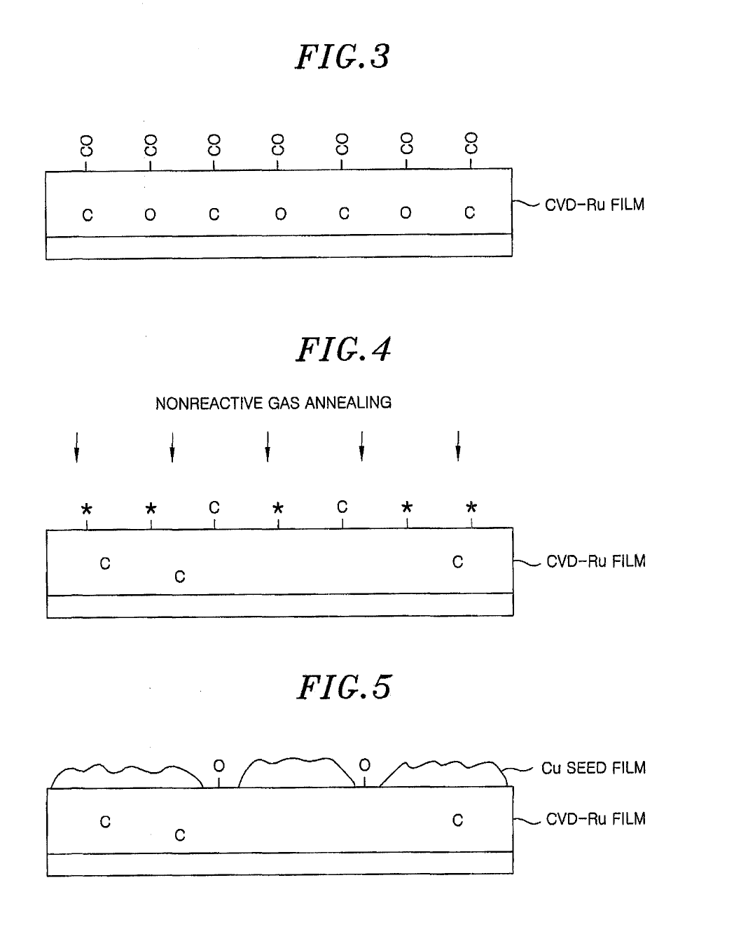

In this film forming process, a large amount of CO is discharged by decomposition of ruthenium carbonyl (Ru₃(CO)₁₂). Hence, as shown in FIG. 3, carbon (C) and oxygen (O) remain as impurities in the CVD-Ru film 15, and the film surface is terminated with CO. In this state, if annealing is performed in a nonreactive gas atmosphere, e.g., an Ar gas atmosphere, as in the conventional case, C and O in the film and CO on the surface are desorbed, and Ru is crystallized. However, C is segregated on the film surface and in the film, as shown in FIG. 4. If C exists on the surface of the CVD-Ru film 15, wetting property of Cu at that portion is deteriorated when the Cu seed film 16 is formed. Accordingly, agglomeration of Cu and discontinuity of the film occur, and a portion that is not covered with Cu exists on the surface of the CVD-Ru film 15, as shown in FIG. 5. In that state, if the wafer is exposed to the atmosphere so that Cu plating can be performed, the surface of the CVD-Ru film 15 which is not covered with Cu is oxidized and turned into RuO₂.

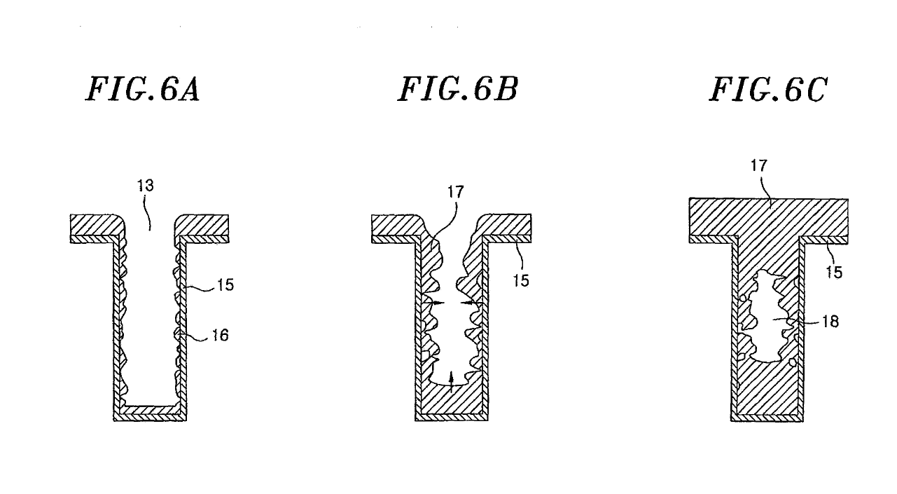

A state in which Cu plating is buried in the trench 13 on which the Cu seed film 16 is formed will be descried with reference to FIGS. 6A to 6C. As shown in FIG. 6A, the discontinuity of the Cu seed film 16 on the CVD-Ru film 15 is noticeable on the sidewall of the trench 13, and a portion of the CVD-Ru film 15 is exposed and turned into RuO₂. Hence, the resistance is increased, and the current density in the trench 13 during Cu plating is decreased. If Cu plating is performed on the discontinuous Cu seed film 16, bottom-up of Cu plating is slowly carried out; a formation density of Cu nucleus is decreased; and a micro-void is generated, as illustrated in FIG. 6B. When the Cu plating proceeds, the opening of the trench 13 is filled (pinch-off) before the trench 13 is completely filled with Cu plating, and a center void 18 is formed, as illustrated in FIG. 6C.

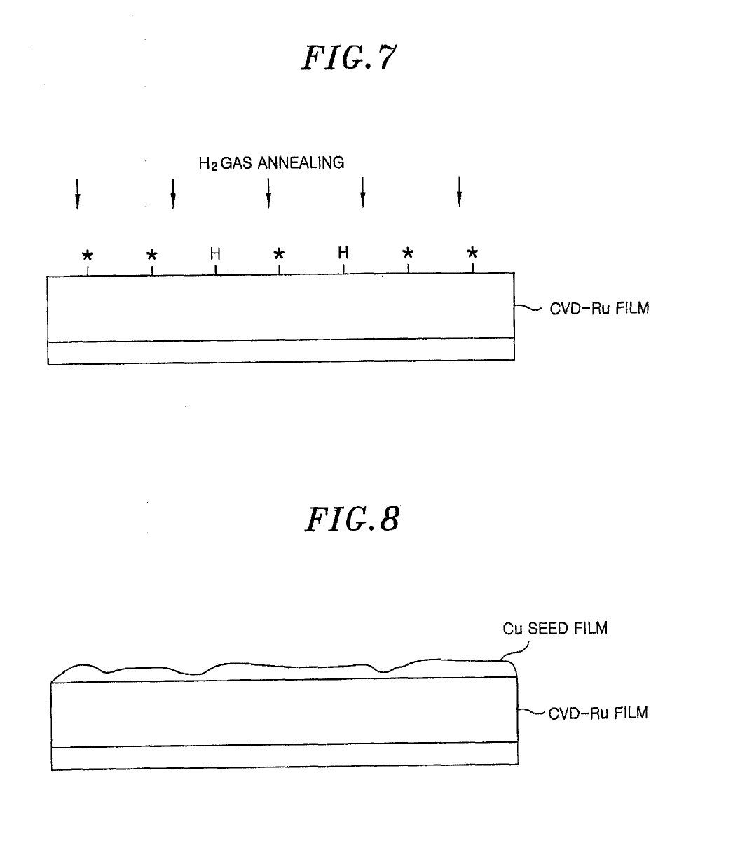

On the other hand, in the present embodiment, the CVD-Ru film 15 is formed in the step 3 and, then, the annealing in a hydrogen containing atmosphere is performed in the step 4. Therefore, as shown in FIG. 7, C and O in the film and CO on the surface are desorbed and Ru is crystallized. At the same time, C is desorbed from the CVD-Ru film 15 by the action of hydrogen. Accordingly, segregation of C on the film surface and in the film does not occur, and the surface of the CVD-Ru film 15 is maintained in a clean state. If the formation of the Cu seed film 16 of the step 5 is performed in this state, Cu easily becomes wet due to the clean surface of the CVD-Ru film 15. Further, the entire surface of the CVD-Ru film 15 is covered with an extremely thin Cu seed film 16 as shown in FIG. 8.

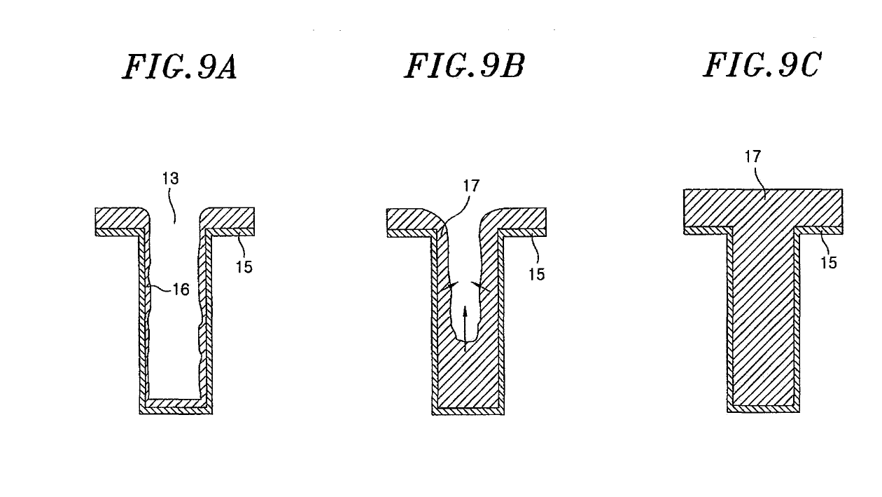

The burial of Cu plating in the trench 13 on which the Cu seed film 16 is formed will be described with reference to FIGS. 9A to 9C. As can be seen from FIG. 9A, the Cu seed film 16 on the CVD-Ru film 15 is continuous and relatively smooth on the sidewall of the trench. Hence, the resistance is small, and the current density in the trench 13 during Cu plating is increased. Accordingly, the bottom-up during Cu plating and the formation of Cu nucleus are rapidly performed as shown in FIG. 9B, and the trench 13 can be filled without generating a void as shown in FIG. 9C.

The annealing in a hydrogen containing atmosphere of the step 4 is performed preferably at about 150° C. to 400° C. If the temperature exceeds about 400° C., adverse effects may be inflicted on the devices. If the temperature is lower than about 150° C., the effect of removing C may be insufficient. In this annealing process, an atmosphere forming gas may be a hydrogen gas or a gaseous mixture of a hydrogen gas and another gas such as a nonreactive gas or the like. At this time, a ratio of the hydrogen gas is preferably about 3% to 100%. Moreover, a hydrogen partial pressure is preferably about 4 Pa to 1333 Pa.

In accordance with the present embodiment, a CVD-Ru film is formed by using a film-forming material containing an organic metal compound and, then, annealing is performed in a hydrogen containing atmosphere. Hence, a residual carbon on the Ru film surface is decreased, and the wetting property of the Cu seed film is improved. Accordingly, the bottom-up and the nucleus formation are rapidly carried out during the Cu plating, and the formation of a void in the Cu plating can be avoided.

### Second Embodiment

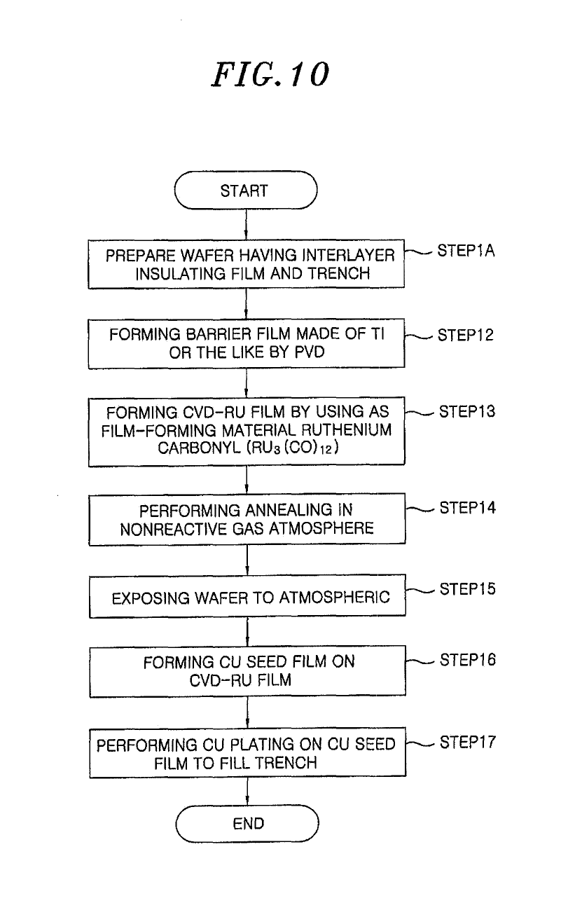

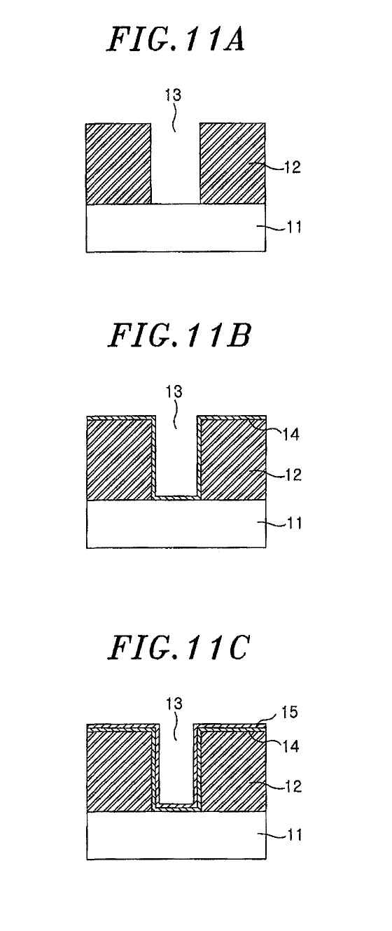

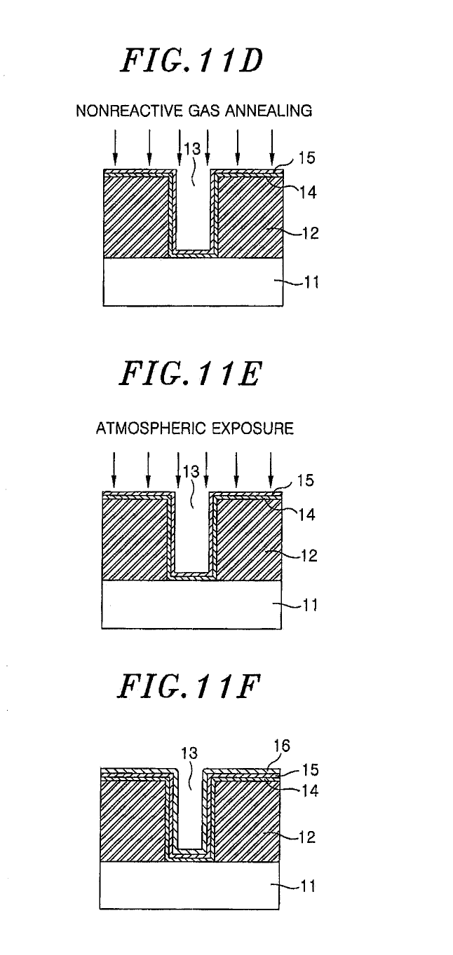

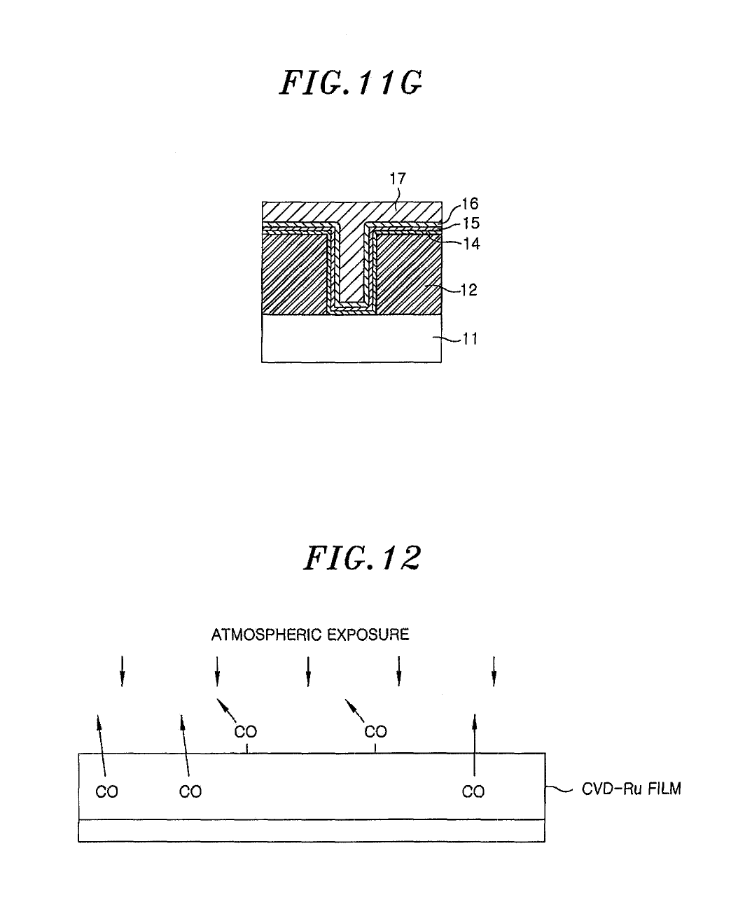

Hereinafter, a second embodiment will be described. FIG. 10 is a flowchart showing a method in accordance with the second embodiment of the present invention. FIGS. 11A to 11G are process cross sectional views of the method of the second embodiment.

In the second embodiment, the same wafer as that used in the step 1 of the first embodiment is prepared (step 11, FIG. 11A). The barrier film 14 is formed as in the step 2 of the first embodiment (step 12, FIG. 11B). Then, the CVD-Ru film 15 is formed as in the step 3 of the first embodiment (step 13, FIG. 11C). Next, instead of annealing in a hydrogen containing atmosphere in the step 4 of the first embodiment, annealing is performed in a nonreactive gas atmosphere, e.g., Ar gas atmosphere (step 14, FIG. 11D). Thereafter, the wafer is exposed to the atmosphere (step 15, FIG. 11E). Next, the Cu seed film 16 is formed on the CVD-Ru film 15 as in the step 5 of the first embodiment (step 16, FIG. 11F). Then, the Cu plating 17 is performed on the Cu seed film 16 to fill the trench 13 (step 17, FIG. 11G).

In the present embodiment, as in the conventional case, the annealing in a nonreactive gas atmosphere of the step 14 is performed after the formation of the CVD-Ru film 15 of the step 13. Therefore, C is segregated on the film surface and in the film, as shown in FIG. 4. However, due to the atmospheric exposure of the step 15, the segregated C is desorbed as CO by oxygen in the atmosphere, and the surface of the CVD-Ru film 15 becomes clean, as shown in FIG. 12. Therefore, when the formation of the Cu seed film 16 of the step 16 is performed, the entire surface of the CVD-Ru film 15 is covered with an extremely thin seed film 16, as in the first embodiment. Further, when the Cu plating of the step 17 is performed, the bottom-up of the Cu plating and the formation of Cu nucleus are effectively carried out, and the trench 13 is filled without generating a void.

The annealing in a nonreactive gas atmosphere of the step 14 is performed preferably at about 150° C. to 400° C. If the temperature exceeds about 400° C., adverse effects may be inflicted on the devices. If the temperature is lower than about 150° C., the effect of removing C may be insufficient. In this annealing process, a pressure in the chamber is preferably about 133 to 1333 Pa. The atmospheric exposure of the step 15 may literally indicate exposure of a silicon substrate to the atmosphere or may indicate introduction of the atmosphere into a chamber in a depressurized atmosphere.

In accordance with the present embodiment, the CVD-Ru film formed by using a film-forming material containing an organic metal compound is subjected to the annealing in a nonreactive gas atmosphere and then to the atmosphere exposure. Accordingly, the bottom-up of the Cu plating and the formation of nucleus are rapidly carried out, and the formation of a void in the Cu plating can be avoided.

Hereinafter, the result of manufacturing semiconductor devices by using the present invention will be described. Here, a wafer having a SiO₂ film serving as an interlayer insulating film formed on a silicon substrate and a trench formed thereon was prepared. A Ti film having a thickness of about 4 nm serving as a barrier film was formed by PVD, and a CVD-Ru film having a thickness of about 4 nm was formed thereon by using ruthenium carbonyl (Ru₃(CO)₁₂). Then, a Cu seed film having a thickness of about 20 nm was formed. At this time, the following five cases were examined: (1) a Cu seed film was formed without annealing; (2) a Cu seed film was formed after performing annealing in an Ar gas atmosphere (conventional case); (3) a Cu seed film was formed after performing annealing in a H₂ gas atmosphere (first embodiment), (4) a Cu seed film was formed after performing annealing in an Ar gas atmosphere and atmospheric exposure (second embodiment); and (5) a Cu seed film was formed after performing annealing in a H₂ gas atmosphere and atmospheric exposure.

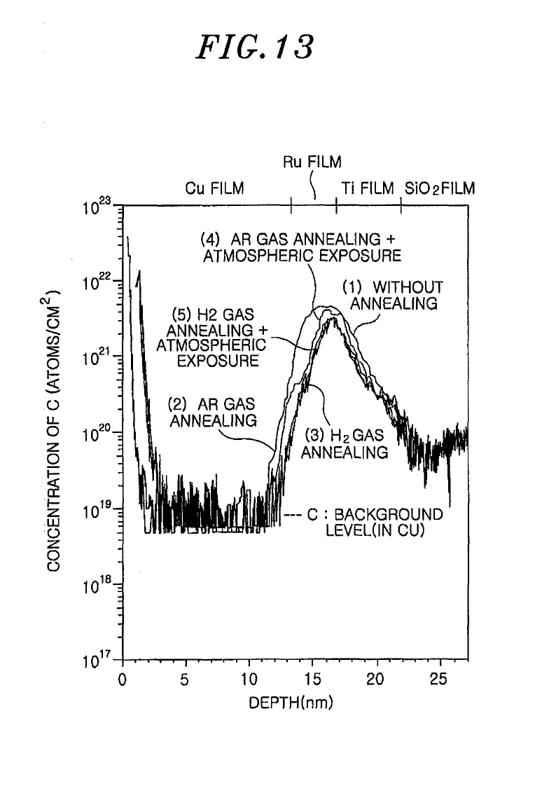

The concentration of C in the film thickness direction in the above-described cases was analyzed by secondary ion mass spectrometry (SIMS). The result thereof is shown in FIG. 13. Referring to FIG. 13, when the annealing is not performed (case (1)), the concentration of C in the CVD-Ru film and in the interface between the CVD-Ru film and the Cu seed film is high. When the annealing is performed as in the cases (2) to (5), the concentration of C in the CVD-Ru film is decreased. However, when a Cu seed film is formed after performing annealing in an Ar gas atmosphere as in the conventional case (case (2)), the concentration of C in the interface between the CVD-Ru film and the Cu seed film is high. On the other hand, when a Cu seed film is formed after performing annealing in a H₂ gas atmosphere as in the first embodiment (case (3)) and when a Cu seed film is formed after performing annealing in an Ar gas atmosphere and atmospheric exposure as in the second embodiment (case (4)), the concentration of C in the interface between the CVD-Ru film and the Cu seed film is decreased. This proves that the concentration of C in the interface between the CVD-Ru film and the Cu seed film affects wetting property of Cu. Further, when a Cu seed film is formed after performing annealing in a H₂ gas atmosphere and atmospheric exposure (case (5)), the concentration of C is slightly increased compared to that measured when a Cu seed film is formed after performing annealing in a H₂ gas atmosphere (case (3)).

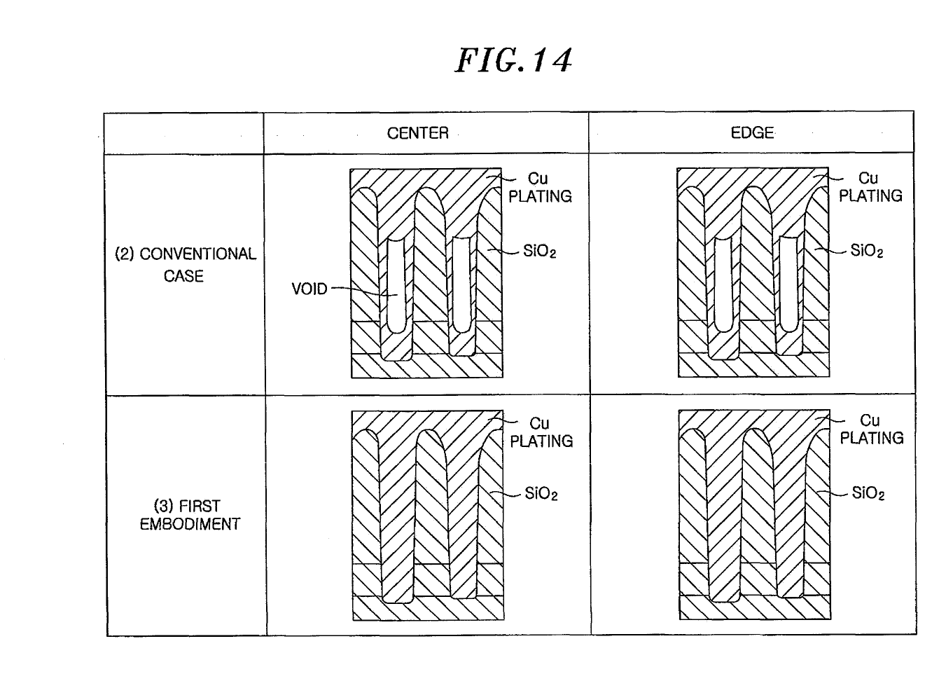

Then, Cu plating was performed on the Cu seed film annealed in an Ar gas atmosphere (case 2, conventional case) and on the Cu seed film annealed in a H₂ gas atmosphere (case 3, first embodiment). The states obtained at that time are shown in FIG. 14. As shown in FIG. 14, in the case 2 (conventional case), large center voids exist in the Cu plating in the trench. However, in the case (3) (first embodiment), the trench is completely filled with Cu plating. In FIG. 14, “center” indicates a state inside the trench near the center of the silicon substrate, and “edge” indicates a state inside the trench near the periphery of the silicon substrate.

Hereinafter, an example of an apparatus used for performing the first and the second embodiment will be described.

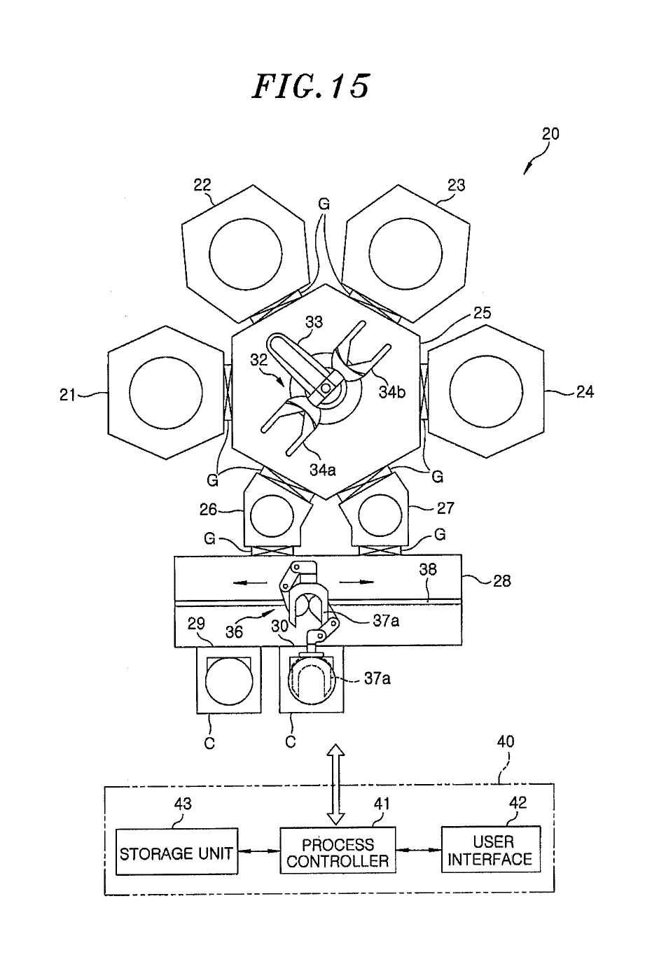

Here, a multi chamber type processing apparatus for consecutively performing the steps 1 to 5 of the first embodiment and the steps 11 to 16 of the second embodiment under a vacuum atmosphere will be described. FIG. 15 is a top view showing the multi chamber type processing apparatus.

A processing apparatus 20 is maintained in a vacuum state. The processing apparatus 20 includes a PVD-Ti film forming unit 21, a CVD-Ru film forming unit 22, an annealing unit 23, and a Cu seed film forming unit 24 which are connected to sides of a hexagonal transfer chamber 25 via gate valves G. Two load-lock chambers 26 and 27 are connected to other sides of the transfer chamber 25 via gate valves G. The transfer chamber 25 is maintained in a vacuum state. A loading/unloading chamber 28 in an atmospheric atmosphere is provided at the side of the load-lock chambers 26 and 27 which is opposite to the side where the transfer chamber 25 is provided, and two carrier attachment ports 29 and 30 to which carriers C capable of accommodating therein wafer W are attached are provided at the side of the loading/unloading chamber 28 which is opposite to the side where the load-lock chambers 26 and 27 are connected.

Provided in the transfer chamber 25 is a transfer device 32 for loading and unloading a wafer into and from the PVD-Ti film forming unit 21, the CVD-Ru film forming unit 22, the annealing unit 23, the Cu seed film forming unit 24, and the load-lock chambers 26 and 27. The transfer device 32 is provided at a substantially central portion of the transfer chamber 25, and has at a leading end of a rotatable and extensible/contractible portion 33 two support arms 34a and 34b for supporting the semiconductor wafer W. The two support arms 34a and 34b are attached to the rotatable and extensible/contractible portion 33 so as to face the opposite directions.

Installed in the loading/unloading chamber 28 is a transfer device 36 for loading/unloading wafers W with respect to the carriers C and the load-lock chambers 26 and 27. The transfer device 36 has a multi-joint arm structure, and can move on a rail 38 along the arrangement direction of the carriers C. The transfer device 36 transfers wafers W mounted on the support arms 37a provided at the leading end thereof.

This processing apparatus 20 includes a control unit 40 for controlling each component thereof. The control unit 40 controls each component of the units 21 to 24, the transfer devices 32 and 36, a gas exhaust system (not shown) of the transfer chamber 25, opening and closing of the gate valves G and the like. The control unit 40 has a process controller 41 having a microprocessor (computer), a user interface 42, and a storage unit 43. The process controller 41 is electrically connected to and controls each component of the processing apparatus 20. The user interface 42 is connected to the process controller 41, and includes a keyboard through which an operator performs a command input to manage each component of the processing apparatus 20, a display for visually displaying the operational state of each component of the processing apparatus 20, and the like. The storage unit 43 is connected to the process controller 41, and stores therein control programs to be used in realizing various processes performed by the processing apparatus 20 under the control of the process controller 41, or programs, i.e., recipes, to be used in operating each component of the processing apparatus 20 to carry out processes under processing conditions, various database and the like. The processing recipes are stored in a storage medium (not shown) provided inside the storage unit 43. The storage medium may be a fixed medium such as a hard disk or the like, or a portable device such as a CD-ROM, a DVD, a flash memory or the like. Alternatively, the recipes may be suitably transmitted from other devices via, e.g., a dedicated transmission line.

If necessary, a predetermined processing recipe is read out from the storage unit 43 under, e.g., the instruction from the user interface 42 and is executed by the process controller 41. Accordingly, a desired process is performed in the processing apparatus 20 under the control of the process controller 41.

In this processing apparatus 20, a wafer W unloaded from a carrier C is transferred to any one of the load-lock chambers 26 and 27 by the transfer device 36 of the loading/unloading chamber 28. Then, the corresponding load-lock chamber is evacuated to a vacuum, and the wafer is unloaded therefrom by the transfer device 32 of the transfer chamber 25 to be transferred to the PVD-Ti film forming unit 21, and a Ti film as a barrier film is formed on an interlayer insulating film, e.g., a SiO₂ film of the wafer W. Next, the wafer W on which the Ti film is formed is transferred to the CVD-Ru film forming unit 22, and a CVD-Ru film is formed thereon. Thereafter, the wafer W on which the Ru film is formed is transferred to the annealing unit 23, and then is subjected to annealing in a hydrogen containing atmosphere or to annealing in a nonreactive gas atmosphere and atmospheric exposure. Then, the annealed wafer W is transferred to the Cu seed film forming unit 24, and a Cu seed film is formed on the CVD-Ru film by, e.g., PVD. The wafer W on which the Cu seed film is formed is transferred to any one of the load-lock chambers 26 and 27 by the transfer device 32. The corresponding load-lock chamber is set to an atmospheric atmosphere and, then, the wafer is returned to the carrier C by the transfer device 36.

The wafer having the Cu seed film is transferred to a Cu plating equipment while being accommodated in a carrier C, and then is subjected to Cu plating.

The following is description of the CVD-Ru film forming unit 22 for forming a CVD-Ru film as a principal part of the present invention.

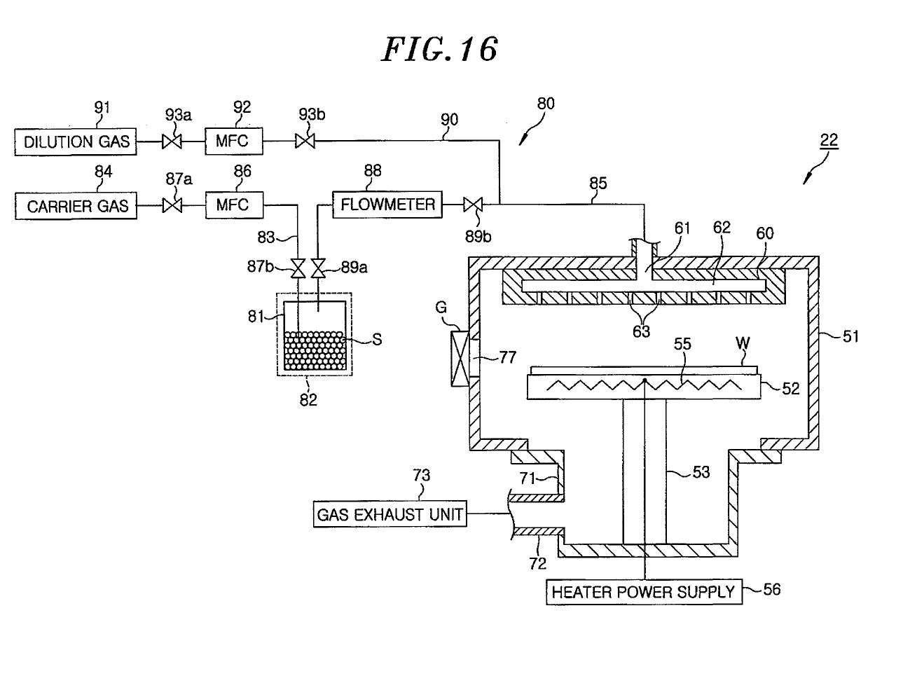

FIG. 16 is a cross sectional view showing the CVD-Ru film forming unit. The CVD-Ru film forming unit 22 includes a substantially cylindrical airtight chamber 51. A susceptor 52 for horizontally supporting a wafer W as a substrate to be processed is supported by a cylindrical support member 53 provided at the center of the bottom portion of the chamber 51. A heater 55 is buried in the susceptor 52, and a heater power supply 56 is connected to the heater 55. The wafer W is controlled to a predetermined temperature by controlling the heater power supply 56 by a heater controller (not shown) based on a detection signal of a thermocouple (not shown) provided at the susceptor 52. In addition, the susceptor 52 is provided with three wafer support pins (not shown) for supporting and vertically moving the wafer W. The three wafer support pins can protrude and retract with respect to the surface of the susceptor 52.

A shower head 60 for introducing a processing gas for CVD film formation into the chamber 51 in a shower shape is provided at the ceiling wall of the chamber 51 so as to face the susceptor 52. The shower head 60 discharges a film forming gas supplied from a gas supply mechanism 80 to be described later into the chamber 51, and has at an upper portion thereof a gas inlet port 61 for introducing a film forming gas. A diffusion space 62 is formed in the shower head 60, and a plurality of injection openings 63 is formed in the bottom surface of the shower head 60.

A gas exhaust chamber 71 is provided at the bottom wall of the chamber 51 so as to protrude downward. A gas exhaust line 72 is connected to the side surface of the gas exhaust chamber 71, and a gas exhaust unit 73 including a vacuum pump, a pressure control valve or the like is connected to the gas exhaust line 72. By driving the gas exhaust unit 73, the interior of the chamber 51 can be set to a predetermined depressurized state.

Formed on the sidewall of the chamber 51 are a loading/unloading port 77 for loading and unloading the wafer W with respect to the wafer transfer chamber 25 and a gate valve G for opening and closing the loading/unloading port 77.

The gas supply mechanism 80 has a film-forming raw material container 81 for storing ruthenium carbonyl (Ru₃(CO)₁₂) as a solid film-forming raw material. A heater 82 is provided around the film-forming raw material container 81. A carrier gas supply line 83 is inserted into the film-forming raw material container 81 from above, and a carrier gas, e.g., CO gas, is supplied from a carrier gas supply source 84 into the film forming raw material container 81 via a carrier gas supply line 83. Further, a gas supply line 85 is inserted into the film forming raw material container 81. The other end of the gas supply line 85 is connected to the gas inlet port 61 of the shower head 60. By supplying the carrier gas into the film forming raw material container 81 via the carrier gas supply line 83, ruthenium carbonyl (Ru₃(CO)₁₂) gas sublimated in the film forming raw material container 81 can be supplied into the chamber 51 via the gas supply line 85 and the shower head 60 while being transferred by the carrier gas.

Besides, a mass flow controller 86 for controlling a flow rate and valves 87a and 87b disposed on both sides thereof are provided in the carrier gas supply line 83. A flowmeter 88 for detecting a flow rate of ruthenium carbonyl (Ru₃(CO)₁₂) gas and valves 89a and 89b disposed on both sides thereof are provided in the gas supply line 85.

A dilution gas supply line 90 for supplying a gas for diluting the film forming raw material gas is connected in the gas supply line 85. The dilution gas supply line 90 is connected to a dilution gas supply source 91 for supplying a dilution gas composed of nonreactive gas such as Ar gas, N₂ gas or the like. By supplying the dilution gas from the dilution gas supply source 91 via the dilution gas supply line 90, the raw material gas is diluted at a proper concentration. The dilution gas from the dilution gas supply source 91 functions as a purge gas for purging a residual gas in the chamber 51 and the gas supply line 85. Moreover, a mass flow controller 92 and valves 93a and 93b disposed on both sides thereof are installed in the dilution gas supply line 90. Further, another gas supply line for supplying another gas, e.g., CO gas, H₂ gas or the like, may be additionally connected to the dilution gas supply line 90.

In the CVD-Ru film forming unit 22 configured as described above, first of all, the gate valve G opens, and the wafer W on which the barrier film is formed is loaded into the chamber 51 from the loading/unloading port 77 and then is mounted on the susceptor 52. Next, the wafer W is heated to about 150° C. to 250° C. via the susceptor 52 by the heater 55. The interior of the chamber 51 is exhausted by the vacuum pump of the gas exhaust unit 73 so that a pressure in the chamber 51 is vacuum-evacuated to about 2 Pa to 67 Pa.

Thereafter, the carrier gas, e.g., CO gas, is supplied into the film forming raw material container 81 via the carrier gas supply line 83 by opening the valves 87a and 87b. Ru₃(CO)₁₂ gas sublimated in the film forming raw material container 81 by heating of the heater 82 is introduced into the chamber 51 via the gas supply line 85 and the shower head 60 while being carried by the carrier gas. At this time, Ru generated on the surface of the wafer W by thermal decomposition of the Ru₃(CO)₁₂ gas is deposited on the Ti film of the wafer W. As a consequence, a CVD-Ru film having a predetermined film thickness is formed. At this time, the flow rate of the Ru₃(CO)₁₂ gas is preferably about 1 mL/min (sccm) to 5 mL/min (sccm). Further, a dilution gas may be introduced at a predetermined ratio.

When the CVD-Ru film having a predetermined film thickness is formed, the supply of the Ru₃(CO)₁₂ gas is stopped by closing the valves 87a and 87b, and the dilution gas from the dilution gas supply source 91 is introduced as a purge gas into the chamber 51 to purge the Ru₃(CO)₁₂ gas. Then, the wafer W is unloaded from the loading/unloading port 77 by opening the gate valve G.

The following is description of the annealing unit 23 for performing annealing after the formation of the CVD-Ru film which is most important in the present invention.

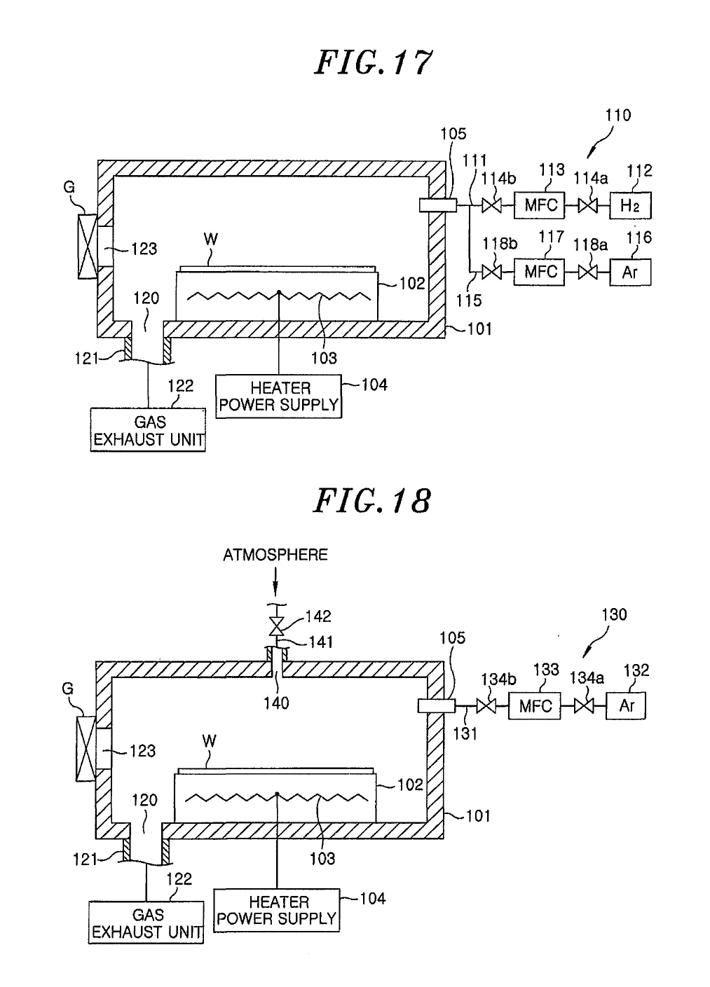

FIG. 17 is a cross sectional view showing an annealing unit which is installed at the processing apparatus of FIG. 15 and performs annealing in a hydrogen containing atmosphere of the first embodiment. The annealing unit includes a substantially cylindrical airtight chamber 101. A susceptor 102 for horizontally supporting a wafer W as a substrate to be processed is disposed at the bottom portion of the chamber 101. A heater 103 is buried in the susceptor 102, and a heater power supply 104 is connected to the heater 103. The wafer W is controlled to a predetermined temperature by controlling the heater power supply 104 by a heater controller (not shown) based on a detection signal of a thermocouple (not shown) provided at the susceptor 102. Further, the susceptor 102 is provided with three wafer elevation pins (not shown) for supporting and vertically moving the wafer W. The wafer elevation pins can protrude and retract with respect to the surface of the susceptor 102.

A gas inlet member 105 is provided at the upper portion of the sidewall of the chamber 101. An atmosphere forming gas is supplied from a gas supply mechanism 110 into the chamber 101 via the gas inlet member 105. The gas supply mechanism 110 includes a H₂ gas supply source 112, and a H₂ gas supply line 111 extending from the H₂ gas supply source 112 to the gas inlet member 105, so that H₂ gas can be introduced into the chamber 101. A mass flow controller 113 for controlling a flow rate and valves 114a and 114b disposed on both sides thereof are installed in the H₂ gas supply line 111. The H₂ gas supply line 111 is connected to an Ar gas supply line 115 for supplying Ar gas as a dilution gas, and the Ar gas supply line 115 is connected to an Ar gas supply source 116. Accordingly, the H₂ gas diluted by the Ar gas can be introduced into the chamber 101. A mass flow controller 117 for controlling a flow rate and valves 118a and 118b disposed on both sides thereof are installed in the Ar gas supply line 115. The dilution gas is not limited to Ar gas, and another dilution gas or another nonreactive gas such as N₂ gas or the like may also be used.

A gas exhaust port 120 is provided at the bottom wall of the chamber 101 and is connected to a gas exhaust line 121. The gas exhaust line 121 is connected to a gas exhaust unit 122 having a vacuum pump, a pressure control valve or the like. By driving the gas exhaust unit 122, the interior of the chamber 101 can be set to a predetermined pressurized state.

Formed on the sidewall of the chamber 101 are a loading/unloading port 123 for loading and unloading the wafer W with respect to the wafer transfer chamber 25 and a gate valve G for opening and closing the loading/unloading port 123.

In the annealing unit configured as described above, first of all, the gate valve G opens, and the wafer W on which the CVD-Ru film is formed is loaded into the chamber 101 from the loading/unloading port 123 and then is mounted on the susceptor 102. Next, the wafer W is heated to about 150° C. to 400° C. via the susceptor 102 by the heater 103. The interior of the chamber 101 is exhausted by the vacuum pump of the gas exhaust unit 122 so that a pressure in the chamber 101 is vacuum-evacuated to about 133 Pa to 1333 Pa.

Next, the hydrogen gas and the dilution gas, e.g., Ar gas, are introduced into the chamber 101 at a flow rate of, e.g., about 10 mL/min (sccm) to 1120 mL/min (sccm) and about 0 mL/min (sccm) to 755 mL/min (sccm), respectively. The annealing is performed in a hydrogen containing atmosphere while setting a hydrogen partial pressure to about 4 Pa to 1333 Pa.

By performing the annealing in a hydrogen containing atmosphere, C and O in the film and Co on the film surface are desorbed, and Ru is crystallized. At the same time, C is desorbed from the CVD-Ru film by the action of hydrogen. Accordingly, segregation of C does not occur on the film surface and in the film, and the surface of the CVD-Ru film is maintained in a clean state. Thus, Cu easily becomes wet during the formation of the Cu seed film, and the entire surface of the CVD-Ru film is covered with an extremely thin Cu seed film.

Upon completion of the annealing process, the supply of the H₂ gas is stopped, and the interior of the chamber 101 is purged with Ar gas. Then, the gate valve G opens, and the wafer W is unloaded from the loading/unloading port 123.

FIG. 18 is a cross sectional view showing an annealing unit which is installed at the processing apparatus of FIG. 15 and performs annealing of the second embodiment. This annealing unit has basically the same structure as that of the annealing unit of FIG. 17. Therefore, like reference numerals refer to like part illustrated in FIG. 17, and the description thereof is omitted.

This annealing unit includes a gas supply mechanism 130 for supplying only Ar gas serving as a nonreactive gas. The gas supply mechanism 130 has an Ar gas supply source 132 and an Ar gas supply line 131 extending from the Ar gas supply source 132 to the gas inlet member 105, so that Ar gas can be introduced into the chamber 101. A mass flow controller 133 for controlling a flow rate and valves 134a and 134b disposed on both sides thereof are provided in the Ar gas supply line 131. The nonreactive gas is not limited to Ar gas, and another reactive gas such as N₂ gas or the like may also be used.

An atmosphere inlet opening 140 is provided at the ceiling wall of the chamber 101 and connected to an atmosphere inlet line 141. Therefore, the atmosphere can be introduced into the chamber 101 via the atmosphere inlet line 141. A valve 142 is installed in the atmosphere inlet line 141.

In the annealing unit configured as described above, first of all, the gate valve G opens, and the wafer W on which the CVD-Ru film is formed is loaded into the chamber 101 from the loading/unloading port 123 and then is mounted on the susceptor 102. Next, the wafer W is heated to about 150° C. to 400° C. via the susceptor 102 by the heater 103. The interior of the chamber 101 is exhausted by the vacuum pump of the gas exhaust unit 122 so that a pressure in the chamber 101 is vacuum-evacuated to about 133 Pa to 1333 Pa.

Then, Ar gas is introduced into the chamber 101 at a flow rate of, e.g., about 7 mL/min (sccm) to 755 mL/min (sccm), and a pressure in the chamber 101 is set to about 133 Pa to 1333 Pa. In this state, the annealing is performed in a nonreactive gas atmosphere. Accordingly, C and O in the film and CO on the film surface are desorbed, and Ru is crystallized. However, C is segregated on the film surface and in the film.

Upon completion of the annealing in an Ar gas atmosphere, the atmosphere is introduced into the chamber 101 via the atmosphere inlet line 141 by opening the valve 142, and the wafer is exposed to the atmosphere. Hence, the segregated C is desorbed as CO by oxygen in the atmosphere, and the surface of the CVD-Ru film becomes clean. Accordingly, Cu becomes wet during the formation of the Cu seed film, and the entire surface of the CVD-Ru film is covered with an extremely thin Cu seed film.

After the annealing is completed, the gate valve G opens, and the wafer W is unloaded from the loading/unloading port 123.

While the invention has been shown and described with respect to the embodiments, the present invention can be variously modified without being limited to the above embodiments. For example, the above-described embodiments have described an example in which a CVD-Ru film is formed by using ruthenium carbonyl (Ru₃(CO)₁₂ as an organic metal compound. However, another organic metal compound such as a pentadienyl compound of ruthenium or the like may be used as the film-forming material without being limited thereto.

The above embodiments have described an example in which a CVD-Ru film and a Cu seed film are formed on a wafer having a trench. However, a wafer having a hole, or a wafer having a trench and a hole may also be used.

The configuration of the apparatus illustrated in the above embodiments is only an example. The apparatus may have other various configurations.

What is claimed is:

1. A CVD-Ru film forming method comprising:
forming a Ru film on a substrate by means of CVD using a ruthenium carbonyl as a film-forming material before forming a Cu film; and
annealing the substrate on which the Ru film is formed in a hydrogen containing atmosphere.

2. The CVD-Ru film forming method of claim 1, wherein the annealing in a hydrogen containing atmosphere is performed at about 150 to 400° C.

3. A CVD-Ru film forming method comprising:
forming a Ru film on a substrate by means of CVD using a ruthenium carbonyl as a film-forming material before forming a Cu film;
annealing the substrate on which the Ru film is formed in a nonreactive gas atmosphere; and
exposing to an atmospheric the Ru film after the annealing in the nonreactive gas atmosphere.

4. The CVD-Ru film forming method of claim 3, wherein the annealing in a nonreactive gas atmosphere is performed at about 150 to 400° C.

5. A semiconductor device manufacturing method comprising:
forming a metal barrier film on a substrate having a trench and/or a hole;
forming a Ru film on the substrate by means of CVD using a ruthenium carbonyl as a film-forming material before forming a Cu film;
annealing the substrate on which the Ru film is formed in a hydrogen containing atmosphere; and
forming on the annealed Ru film a Cu seed film for burying Cu plating in the trench and/or the hole.

6. The CVD-Ru film forming method of claim 5, wherein the annealing in a hydrogen containing atmosphere is performed at about 150 to 400° C.

7. A semiconductor device manufacturing method comprising:
forming a metal barrier film on a substrate having a trench and/or a hole;
forming a Ru film on the substrate by means of CVD using a ruthenium carbonyl as a film-forming material before forming a Cu film;
annealing the substrate on which the Ru film is formed in a nonreactive gas atmosphere;
exposing to an atmospheric the Ru film after the annealing in the nonreactive gas atmosphere; and
forming on the annealed Ru film a Cu seed film for burying Cu plating in the trench and/or the hole.

8. The CVD-Ru film forming method of claim 7, wherein the annealing in a nonreactive gas atmosphere is performed at about 150 to 400° C.

9. A non-transitory computer-readable storage medium storing a program for controlling a processing apparatus, wherein the program, when executed by a computer, controls the processing apparatus to perform the semiconductor device manufacturing method described in claim 5.

10. A non-transitory computer-readable storage medium storing a program for controlling a processing apparatus, wherein the program, when executed by a computer, controls the processing apparatus to perform the semiconductor device manufacturing method described in claim 7.
